(19) United States
(12) Patent Application Publication
(10) Pub. No.: US 2024/0008285 A1
(43) Pub. Date: Jan. 4, 2024

(54) BACKSIDE REVEAL FOR LAYERED MULTI-CAPACITOR SINGLE TRANSISTOR MEMORY SYSTEMS

(71) Applicant: Intel Corporation, Santa Clara, CA (US)

(72) Inventors: Abhishek Anil Sharma, Portland, OR (US); Anand Murthy, Portland, OR (US); Wilfred Gomes, Portland, OR (US); Tahir Ghani, Portland, OR (US)

(73) Assignee: Intel Corporation, Santa Clara, CA (US)

(21) Appl. No.: 17/856,877

(22) Filed: Jul. 1, 2022

(51) Int. Cl. H01L 27/11514; H01L 29/78; H01L 29/66; H01L 29/06

(52) U.S. Cl. CPC H01L 27/11514; H01L 29/0673; H01L 29/6684; H01L 29/78391

(57) ABSTRACT

Bits are stored in an array with multiple capacitors sharing a single access transistor and a common plate coupled to the transistor. A single common select transistor accesses information stored in an array of capacitors, above and below the transistor and sharing a common plate. The common plate may be vertical and encircled by each of the other plates. The capacitors may be ferroelectric capacitors. In an integrated circuit system, the array may be coupled to a power supply and a cooling structure.

### BACKGROUND

Memory performance and cost pressures drive a continuous and ever-increasing demand for denser, cheaper, more stable, and less volatile memory devices. Density improvements in random-access memory (RAM) devices could readily improve and enable larger and more complex devices. For example, system performance can be improved by using denser ferroelectric random-access memory (FeRAM) in place of other less-dense or more-volatile memory devices. More complex systems can be made better or less expensive with denser and cheaper FeRAM.

Structures and methods are needed to improve RAM devices and the larger systems in which the RAM devices are deployed. It is with respect to these and other considerations that the present improvements have been needed. Such improvements may become critical as the desire to improve RAM become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional profile view of a memory device, including an array of capacitors with a common plate coupled to an access transistor;

FIG. 2 illustrates an isometric view of a memory device, including an array of capacitors with a common plate coupled to an access transistor;

FIG. 3 illustrates a cross-sectional profile view of a memory device, including an array of capacitors with a recessed common plate coupled to an access transistor;

FIG. 4 illustrates a cross-sectional profile view of a memory device, including upper and lower arrays of capacitors with a common plate coupled to an access transistor;

FIG. 5 illustrates a cross-sectional profile view of a memory device, including upper and lower arrays of capacitors with a recessed, common plate coupled to an access transistor;

FIG. 6 illustrates a cross-sectional profile view of a memory device, including multiple access transistors, each coupled to upper and lower arrays of capacitors sharing a common plate;

FIGS. 7A and 7B illustrate schematic views of a memory device, including arrays of access transistor and capacitors in an integrated circuit (IC) die;

FIG. 8 illustrates various processes or methods for forming a layered, programmable capacitor array with shared common plate and single access transistor;

FIG. 9 illustrates a cross-sectional view of a low-temperature IC system having layered capacitor memory arrays with single access transistors and using die- and package-level active cooling;

FIG. 10 illustrates a view of an example two-phase immersion cooling system for low-temperature operation of an IC system;

FIG. 11 illustrates a diagram of an example data server machine employing an IC system having layered capacitor memory arrays with single access transistors; and

FIG. 12 is a block diagram of an example computing device, all in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the density of random-access memory (RAM) devices, e.g., ferroelectric RAM (FeRAM) devices. Many RAM devices store data in capacitors. For example, FeRAM devices store data in ferroelectric capacitors. RAM density can be increased by storing multiple bits per access transistor, e.g., by connecting multiple storage capacitors to a single transistor, and by sharing capacitor plates among multiple capacitors. Multiple capacitors can share a common first plate with multiple second plates, e.g., wrapping around the common, inner plate. Memory density can also be increased by using vertical space for memory arrays and routing to use less area laterally. For example, the shared plate (and platelines connecting to the other plates) can extend vertically from the access transistor. Further area can be saved by using vertical space both above and below memory cells, e.g., by forming capacitor memory arrays on both front and back sides of an integrated circuit (IC) die. RAM density can be increased further still by increasing component densities with decreased component sizes. Small access transistors with narrow channels, e.g., within fins, nanowires, nanoribbons, or nanosheets can be laid out tightly and with small pitches. Advantageously, system temperatures can be reduced to increase conductances and reduce leakage currents, thereby enabling still smaller component sizes.

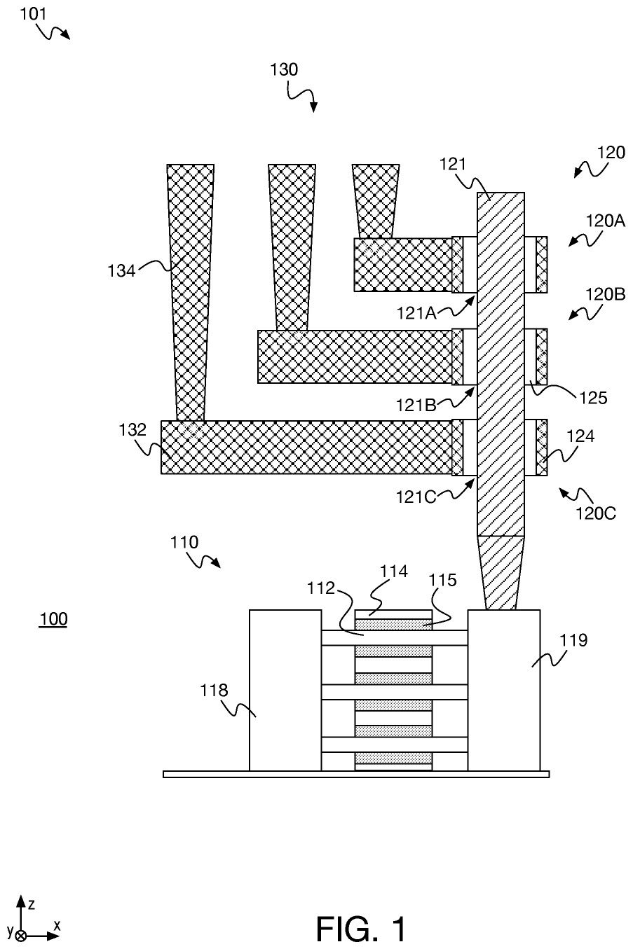

FIG. 1 illustrates a cross-sectional profile view of a memory device 101, including an array of capacitors 120 with a common plate 121 coupled to an access transistor 110, in accordance with some embodiments. As shown, array of capacitors 120 is above select or access transistor 110. Capacitors 120 have outer, separate plates 124 that surround an inner common plate 121, which is a shared plate for all capacitors 120 in array of capacitors 120. Capacitors 120 have an insulator 125, e.g., a ferroelectric material or other dielectric material, between common plate 121 and separate plates 124. Each capacitor 120 is connected to a plateline 130, which each have a horizontal portion 132 and a vertical portion 134. Horizontal portions 132 connect to separate plates 124 of each capacitor 120, and vertical portions 134 connect to horizontal portions 132 and route vertically away from access transistor 110. Memory device 101 is within an IC die 100, but other contexts are possible.

Access transistor 110 is a non-planar transistor and includes a channel 112, gate electrode 114, and gate dielectric 115. Channel 112 is within a nanowire or nanosheet and extends the length of gate electrode 114. As used herein, the term channel indicates a structure that may be activated during operation. The channel may be characterized as a channel structure, semiconductor material structure, or the like. Source contact 119 and drain contact 118 connect to either end of access transistor 110. Source contact 119 connects to the source end of channel 112, and drain contact 118 connects to the drain end of channel 112. In some embodiments, access transistor 110 is a structurally and electrically symmetric field-effect transistor (FET), e.g., currents will flow in both directions approximately equally, and the source and drain ends of channel 112 are interchangeable. Although a source or drain terminal or contact may be specified in some instances, such usage is not limiting in the context of this description. Either terminal can be used in place of the other in the provided examples.

Access transistor 110 can be of any suitable type. In some embodiments, access transistor 110 is a planar FET. Advantageously, access transistor 110 is sufficiently conductive while not occupying overly much lateral area. In some embodiments, access transistor 110 is a non-planar transistor, such as a FinFET, where channel 112 is within a fin, a relatively thin vertical semiconductor structure under gate dielectric 115 and gate electrode 114. In some embodiments, access transistor 110 is a non-planar transistor, and channel 112 is within a nanoribbon, nanowire or nanosheet with gate dielectric 115 and gate electrode 114 vertically around the nanoribbon, nanowire or nanosheet, including channel 112. Such non-planar transistors provide increased conductance relative to at least some other types and can be formed with very small dimensions, e.g., channel thicknesses. In some embodiments, access transistor 110 is a non-planar transistor, and channel 112 has channel thickness of not more than 2 nm. Suitable materials with sufficient conductivity can be used, and system conditions can be manipulated to enhance transistor conductance. In some embodiments, memory device 101 and IC die 100 are coupled to a power supply through a substrate as part of an IC system, and the IC system includes a cooling structure capable of removing, and configured to remove, heat from the IC die to lower the operating temperature to below 0° C. In some embodiments, memory device 101 and IC die 100 are coupled to a power supply through a substrate as part of an IC system, and the IC system is thermally coupled to a cooling structure capable of removing, and configured to remove, heat from the IC die to lower the operating temperature to below 0° C. Low temperature operation may allow for improved performance such as improved mobility and reduced leakage that allow for very small channel thicknesses.

Gate dielectric 115 is an insulator between gate electrode 114 and channel 112 such that the gate structure is in contact with channel 112, but the control signal on gate electrode 114 is not electrically connected through to channel 112. With gate dielectric 115 as part of the gate structure, an electric field with strength proportional to the control voltage on gate electrode 114 modulates conduction through channel 112. Gate dielectric 115 may have multiple layers. The one or more layers of gate dielectric 115 may include silicon oxide, silicon dioxide (SiO₂), and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in gate dielectric 115 include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

Gate electrode 114 can be of any material suitable for controlling current through channel 112, e.g., a metal for establishing the gate field. Gate electrode 114 may include one layer or a stack of layers. Gate electrode 114 is on gate dielectric 115 and may include of at least one of a p-type work function metal or an n-type work function metal, depending on whether the transistor is, e.g., a PMOS or an NMOS transistor. In some embodiments, gate electrode 114 is a stack of two or more metal layers, where one or more metal layers are work function metal layers and at least one metal layer is a fill metal layer. In some embodiments, gate electrode 114 includes titanium and nitrogen. In some embodiments, gate electrode 114 includes tantalum and nitrogen. In some embodiments, gate electrode 114 includes tungsten. In some such embodiments, gate electrode 114 includes tungsten and nitrogen. In some embodiments, gate electrode 114 includes cobalt or ruthenium. In some embodiments, gate electrode 114 includes molybdenum.

Select or access transistor 110 controls the access to the memory array by electrically connecting (or not) inner common plate 121 to, e.g., a bitline connected to the opposite end of access transistor 110 at drain contact 118. When access transistor 110 conducts, common plate 121 on source contact 119 is electrically connected to drain contact 118 and, e.g., a bitline. The conduction of access transistor 110 is controlled by the voltage signal applied to gate electrode 114, e.g., by a wordline. Since common plate 121 is a shared plate for all capacitors 120 in the group, any bit stored in any of the group's capacitors 120 is accessible by the single access transistor 110.

While all capacitors 120 share the inner common plate 121, each capacitor 120 includes its own individual, exclusive portion of common plate 121. For example, common plate 121 is shared as a common inner plate by array of capacitors 120 (e.g., capacitors 120A, 120B, 120C). Each capacitor 120 includes its own divided portion of the shared plate, that part of common plate 121 where a separate plate 124 encircles the shared plate. For example, capacitors 120A, 120B, 120C include their exclusive portions of common plate 121A, 121B, 121C, respectively. These other plates, separate plates 124, are outer plates around a cylindrical, inner common plate 121, which may be an advantageous geometry for forming a memory array of capacitors 120 with a common plate 121. This coaxial geometry efficiently provides capacitor plate surface area for a given capacitor volume while allowing for simple manufacture of a vertical shared plate with outer plates easily accessible from any lateral direction, i.e., all 360° in a horizontal plane. The vertical orientation of the shared plate and the associated array of capacitors 120 conserves lateral area, but is not required. Coaxial plates are not required. Other orientations (e.g., horizontal) and geometries (e.g., parallel planar plates) can be used.

With access transistor 110 accessing the entire memory array of capacitors 120 via common plate 121, individual control of capacitors 120 is by controlling the other plates, separate plates 124, using platelines 130 (in concert with access transistor 110 using, e.g., a wordline). With access transistor 110 conducting, an individual bit corresponding to one of capacitors 120 can be read (or written) by applying a voltage differential across that capacitor 120 (and only that capacitor 120) by applying the same voltage level on drain contact 118 and all platelines 130 but for the plateline 130 connected to the separate plate 124 corresponding to the capacitor 120 to be read (or written). In this way, a voltage can be applied across common plate 121 and an individual separate plate 124 to charge (or write to) or discharge (or read from) only that capacitor 120. Control of storage capacitors 120 may vary with the type of capacitor 120, e.g., depending on the material of insulator 125.

In the examples shown in FIG. 1 and below, insulator 125 may be a ferroelectric material with a high relative permittivity. A capacitor with a higher relative permittivity can have smaller plate dimensions for the same capacitance value. A capacitor with smaller plate dimensions can have the same capacitance value by proportionally decreasing the distance between the capacitor plates. In some embodiments, capacitors 120 have a ferroelectric material thickness of 20 nm. Insulator 125 advantageously includes a ferroelectric material with a higher relative permittivity than high-K dielectric materials that lack the spontaneous polarization of materials in a ferroelectric phase (orthorhombic, non-centrosymmetric crystallinity). For example, a high-k dielectric comprising predominantly hafnium and oxygen (HfOₓ), but not in a ferroelectric phase, may have a relative permittivity in the range of 10-14. However, hafnium oxide in a ferroelectric phase may have a relative permittivity exceeding 25 (e.g., 30). Although in both instances the HfOₓ comprises predominantly hafnium and oxygen, insulator 125 advantageously includes a ferroelectric phase of a material, e.g., hafnium oxide. In the case of hafnium oxide, such phases may be achieved, for example, through the addition of a dopant, such as niobium, titanium, silicon, germanium, aluminum, yttrium, etc.

Many ferroelectric materials are suitable for use in insulator 125. As used herein, the term ferroelectric material indicates a material that has a spontaneous electric polarization that may be controlled by the application of an external electric field. Ferroelectric materials exhibit a hysteresis such that when a positive voltage is applied, a positive residual charge is maintained even as the voltage falls to zero. This residual charge is characterized as polarization. To remove the polarization, a negative voltage must be applied. Furthermore, the negative voltage may be used to provide a negative polarization, which is also maintained as the voltage again goes to zero. In capacitors 120 and other capacitor structures discussed herein, a differential voltage must be applied across a ferroelectric capacitor to polarize insulator 125 (i.e., the ferroelectric material) either positively or negatively. This positive or negative polarity may then be read as 1 or 0. Besides the advantage of higher relative permittivity, ferroelectric materials and this polarization have this non-volatility advantage over non-ferroelectric dielectric materials.

In some embodiments, insulator 125 includes lead, zirconium, titanium, and oxygen (e.g., lead zirconium titanate, Pb[ZrₓTi₁₋ₓ]O₃, (PZT)). In some embodiments, insulator 125 includes barium, titanium, and oxygen (e.g., barium titanate, BaTiO₃). In some embodiments, insulator 125 includes lead, titanium, and oxygen (e.g., lead titanate, PbTiO₃). In some embodiments, insulator 125 includes barium, strontium, titanium, and oxygen (e.g., barium strontium titanate, BaSrTiO₃). Other ferroelectric materials may be employed.

Advantageously, insulator 125 includes a ferroelectric material that may be deposited conformally and to very narrow thicknesses, such as a two-dimensional (2D) material. Such is the case with numerous oxides of hafnium or similar metals. In some embodiments, insulator 125 includes hafnium, zirconium, and oxygen (HZO) (e.g., hafnium zirconium oxide, Hf₁₋ₓZrₓO₂). In some such embodiments, insulator 125 includes dopants, e.g., titanium or niobium. In some embodiments, insulator 125 includes hafnium, titanium, and oxygen (e.g., hafnium titanium oxide, Hf₁₋ₓTiₓO₂). In some embodiments, insulator 125 includes hafnium, scandium, and oxygen. In some embodiments, insulator 125 includes zirconium and oxygen (e.g., zirconium dioxide, ZrO₂) In some embodiments, insulator 125 includes niobium and oxygen. Although, e.g., hafnium zirconium oxide or doped HfOₓ are exemplary embodiments that can be advantageously conformally deposited by atomic layer deposition (ALD), insulator 125 may also have other compositions similarly amenable to being deposited at temperatures compatible with, e.g., back-end-of-line (BEOL) structures and with similar thickness conformality.

The use of 2D ferroelectric materials allows for arrays with smaller capacitors and increased memory density. In some embodiments, capacitors 120 have a ferroelectric material thickness of 10 nm. In some embodiments, capacitors 120 have a ferroelectric material with a capacitance of at least 1 fF. Capacitors can maintain a given capacitance value with reduced plate areas by proportionally reducing their ferroelectric (or other dielectric) material thicknesses. In some embodiments, capacitors 120 have a ferroelectric material thickness of 2 nm. In some embodiments, capacitors 120 have a ferroelectric material with a capacitance of not more than 30 fF. Non-ferroelectric materials may also be employed in insulator 125.

As with transistor conductance, capacitor performance can be enhanced by manipulating system operating conditions. Active cooling structures can lower operating temperatures, which can lower charge leakage. Higher capacitance values can sufficiently store data without excessive disturb issues. Smaller dimensions and voltages may be used. In some embodiments, capacitors 120 have a ferroelectric material with a capacitance of at least 0.1 fF. In some embodiments, capacitors 120 have a ferroelectric material with a capacitance of not more than 5 fF.

As discussed, capacitors 120 are controlled by coordinating the voltage levels on both plates, inner common plate 121 and outer separate plates 124, for each capacitor 120 individually. Common plate 121 is controlled by access transistor 110 and separate plates 124 are controlled by their corresponding platelines 130, which each include horizontal portion 132 and vertical portion 134. Separate plates 124 are coupled to vertical portions 134 by horizontal portions 132, and vertical portions 134 route upward, away from access transistor 110, which conserves lateral area and promotes memory density. With coaxial separate plates 124, horizontal portions 132 can extend laterally away from common plate 121 at different angles in a horizontal plane. In some embodiments, this is not an option, e.g., for coaxial separate plates 124 in a same vertical plane, e.g., when routing options are constrained or separate plates 124 are too numerous. In the co-planar example of FIG. 1, horizontal portion 132 coupled to separate plate 124 proximate access transistor 110, e.g., lowest and closest to access transistor 110 in FIG. 1, extends further laterally than horizontal portion 132 coupled to separate plate 124 distal access transistor 110, e.g., away from access transistor 110 and above proximate separate plate 124. This provides lateral space for both vertical portions 134 to extend upward from their respective horizontal portions 132 with vertical portion 134 coupled to the distal separate plate 124 between common plate 121 and vertical portion 134 coupled to proximate separate plate 124.

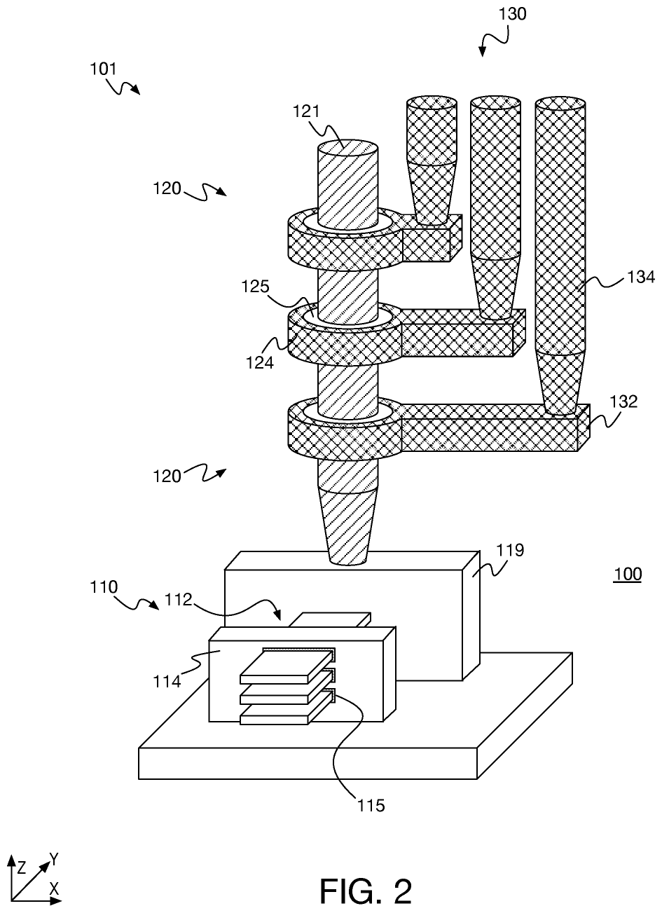

FIG. 2 illustrates an isometric view of memory device 101, including an array of capacitors 120 with common plate 121 coupled to access transistor 110, in accordance with some embodiments. Memory device 101 is similar to the embodiment described in FIG. 1 and is also within an IC die 100. Some differences between the embodiments in FIG. 1 and FIG. 2 allow for clear viewing of the structures in the isometric view of FIG. 2. For example, access transistor 110 is viewed from the side with drain contact 118, but drain contact 118 is not shown, which leaves visible a cross-sectional view of nanoribbons or nanosheets. The nanoribbons or nanosheets that include channel 112 extend in the y direction in FIG. 2, which provides a different perspective of gate electrode 114. Channel 112 is obscured by gate electrode 114, but extends the length of gate electrode 114 within the nanoribbons or nanosheets. Gate dielectric 115 can be seen wrapping around the nanoribbons or nanosheets, which insulates channel 112 from gate electrode 114. Horizontal portions 132 of platelines 130 are again co-planar and aligned with the x direction, which allows unobscured viewing of capacitors 120, including separate plates 124, which are coupled to horizontal portions 132. Insulators 125 is between common plate 121 and separate plates 124, which encircle insulators 125 and common plate 121 horizontally.

Common plate 121 is above access transistor 110, coupled to source contact 119, and extends vertically upwards. The vertical orientation of common plate 121 and the vertical routing of platelines 130 via vertical portions 134 conserves lateral area and allows for an entire word group of bits, stored within the array of capacitors 120, to be laterally confined to the footprint of the single select or access transistor 110. Lateral space is saved, e.g., by sharing common plate 121 and access transistor 110 among multiple storage capacitors 120, routing platelines 130 vertically, and using relatively small components. For example, storage capacitors 120 are effectively larger (but actually smaller than they might otherwise be) because of their efficient structure, wrapping around common plate 121 and providing sufficient capacitor plate are within a relatively small capacitor volume. Other capacitor structures may be yet more efficient.

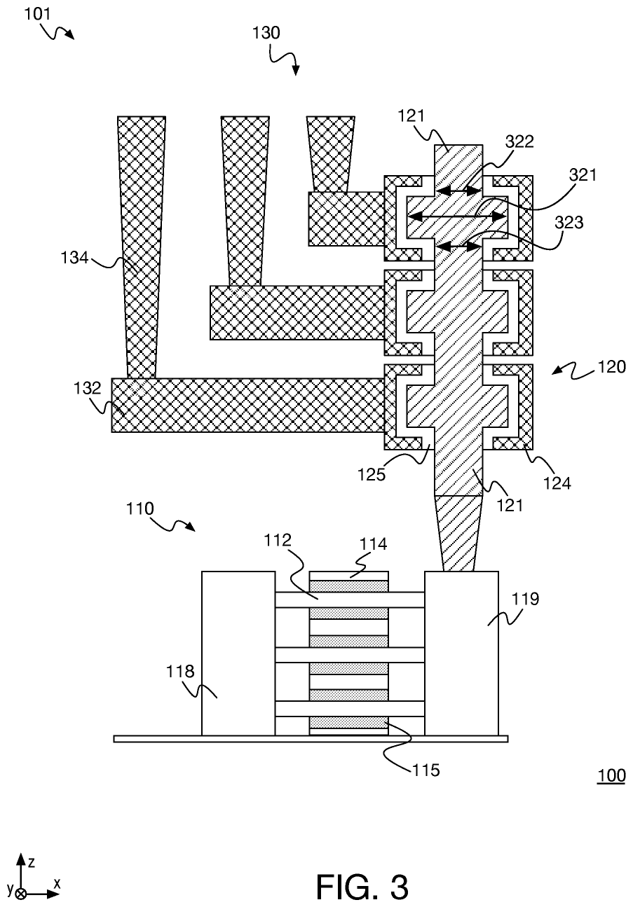

FIG. 3 illustrates a cross-sectional profile view of memory device 101, including an array of capacitors 120 with a recessed common plate 121 coupled to access transistor 110, in accordance with some embodiments. Memory device 101 is similar to the embodiment described in FIG. 1 but uses a different structure for capacitors 120 with, e.g., a recessed common plate 121. The common plate 121 may be recessed in to narrower thicknesses or formed wider at the wider thicknesses. The cross-sectional profile view of capacitors 120 shows that the individual, divided portion (or exclusive portion) of the shared plate, common plate 121, of each capacitor 120 has a first thickness 321 below a second thickness 322 and above a third thickness 323, with first thickness 321 being wider than the second and third thicknesses 322, 323.

This new structure provides higher capacitance values given the same capacitor volume and external dimensions or, e.g., the same capacitance values with smaller capacitor volume and external dimensions. The structure provides higher capacitance values by increasing the parallel plate area of capacitors 120. Common plate 121 is narrower at the tops and bottoms of each capacitor 120 (or wider at the vertical center of each capacitor 120). Besides the curved surface (e.g., perpendicular to a radius of common plate 121), separate plates 124 are now also parallel to common plate 121 with horizontal surfaces near the tops and bottoms of each capacitor 120.

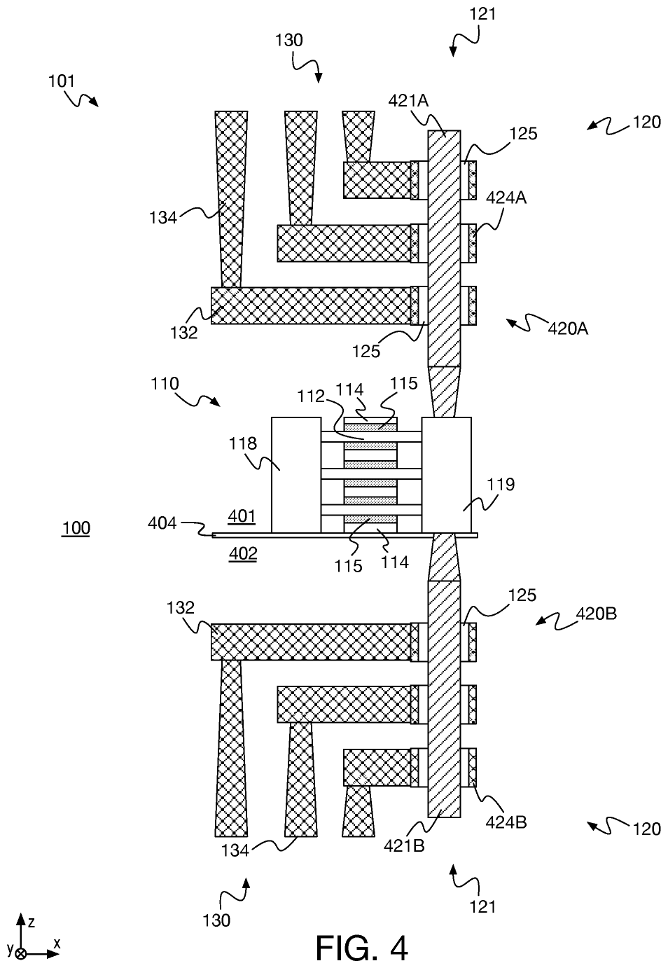

FIG. 4 illustrates a cross-sectional profile view of memory device 101, including upper and lower arrays of capacitors 120 with common plate 121 coupled to access transistor 110, in accordance with some embodiments. Memory device 101 is similar to the embodiment described in FIG. 1 but employs upper and lower arrays of capacitors 120 (or upper and lower sets in a single array of capacitors 120). By more effectively using volume within IC die 100, e.g., by using unexploited vertical space, this can double the memory storage density by providing twice as many storage capacitors 120 within the same lateral area. Platelines 130 are routed vertically upward and downward via vertical portions 134.

A group of upper capacitors 420A includes an upper common plate 421A and a group of upper outer plates 424A. Upper common plate 421A is coupled to and above the source and source contact 119. Each of upper capacitors 420A includes one of upper outer plates 424A, an individual or divided portion of upper common plate 421A, and an insulator 125. Similarly, a group of lower capacitors 420B includes a lower common plate 421B and a group of lower outer plates 424B. Lower common plate 421B is coupled to and below the source and source contact 119. Each of lower capacitors 420B includes one of lower outer plates 424B, an individual or divided portion of lower common plate 421B, and an insulator 125. Upper and lower capacitors 420A, 420B are part of a same word group accessed by the same access transistor 110. Accordingly, upper and lower capacitors 420A, 420B can also be thought of as upper and lower sets of capacitors 120, the lower set below the select transistor and the upper set above the select transistor (access transistor 110). Likewise, upper and lower outer plates 424A, 424B can be thought of as upper and lower sets of separate plates 124, a lower set of outer plates and an upper set of outer plates. Upper common plate 421A and lower common plate 421B, both coupled and electrically connected to source contact 119, can be thought of as an upper region and a lower region of a single, inner common plate 121. In some embodiments, upper common plate 421A and lower common plate 421B are formed together with source contact 119 into an integrated inner common plate 121.

Upper and lower capacitors 420A, 420B can be formed and situated by any suitable means and in any suitable location. Upper and lower capacitors 420A, 420B are vertically aligned, which ensures conservation of lateral area, but they need not be. Upper and lower capacitors 420A, 420B are vertically oriented, which also conserves lateral area, but they need not be. Upper capacitors 420A are on a front side 401 of IC die 100, and lower capacitors 420B are on a back side 402, above and below an etch-stop layer 404, respectively. This allows for simple manufacture of the transistor and upper capacitors 420A before forming lower capacitors 420B on a back side, but other situations of the capacitors in IC die 100 are allowable. Upper and lower capacitors 420A, 420B need not be symmetrical. The arrays can be of different sizes, i.e., an upper set of capacitors can have more or fewer capacitors than a lower set.

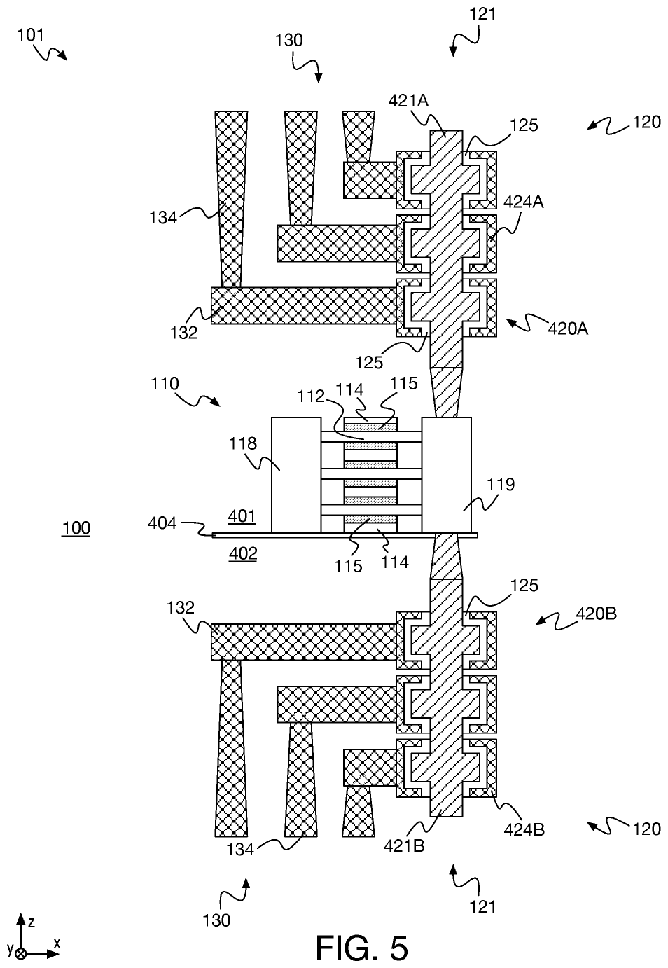

FIG. 5 illustrates a cross-sectional profile view of memory device 101, including upper and lower arrays of capacitors 120 with recessed, common plate 121 coupled to access transistor 110, in accordance with some embodiments. Memory device 101 is similar to the embodiment described in FIG. 4, with upper and lower sets of capacitors 120, but employs a different structure for capacitors 120 with, e.g., a recessed common plate 121 (as seen in FIG. 3) both above and below access transistor 110.

The recessed structure of capacitors 120 can be used to make smaller capacitors 120 with the same materials and capacitance values or, e.g., to make capacitors 120 with similar capacitance values but with larger dimensions (e.g., insulator 125 thickness) or insulator 125 materials with lower relative permittivity. In some embodiments, different insulator 125 materials are used on a front side 401 and back side 402, e.g., for compatibility with different process flows, and different structures are used in upper and lower capacitors 420A, 420B. For example, capacitors 120 with a recessed common plate 121 and insulator 125 with PZT may be used on front side 401 and a constant-width common plate 121 and insulator 125 with HZO may be used on back side 402.

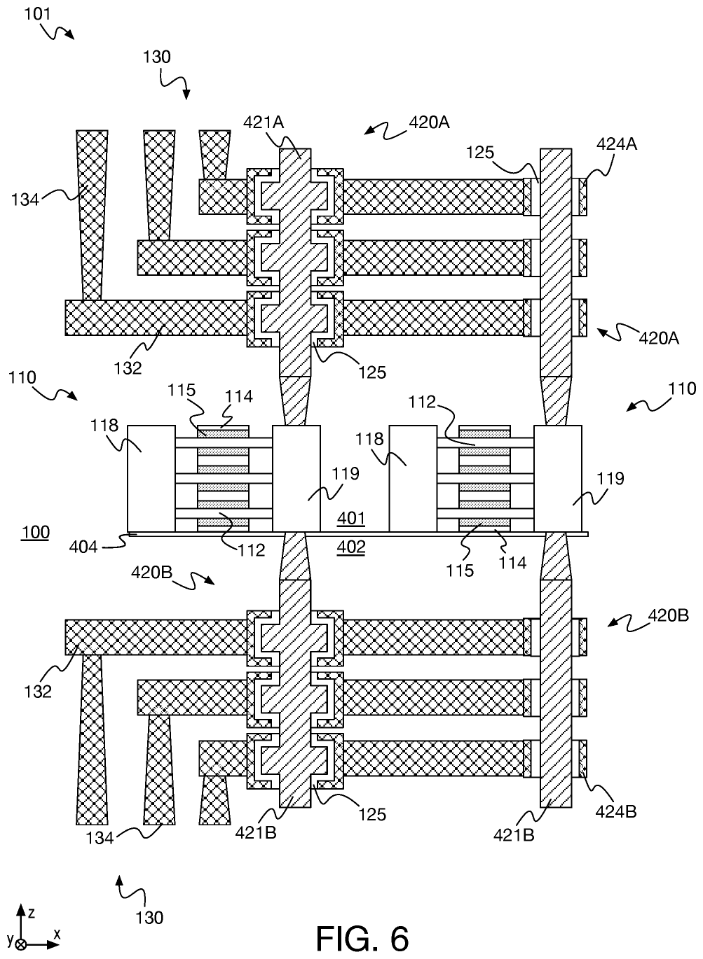

FIG. 6 illustrates a cross-sectional profile view of memory device 101, including multiple access transistors 110, each coupled to upper and lower arrays of capacitors 120 sharing a common plate 121, in accordance with some embodiments. Platelines 130 couple capacitors 120 in separate arrays with different common plates 121. Platelines 130 are routed horizontally above and below access transistors 110 but are routed vertically, e.g., at the edge of a group of memory cells. Signal routing need not use any more lateral area than already utilized by access transistors 110. Multiple and longer (or taller) common plates 121 can be used with longer arrays with more capacitors 120, both above and below source contacts 119, in front and back sides 401, 402, coupled to multiple access transistors 110 to compound the memory density improvements in IC die 100. Multiple and various types and sizes of capacitors 120 may be used to, e.g., maximize capacitance values, minimize dimensions, or accommodate manufacturing processes.

Multiple capacitors 120 are coupled to each other by common platelines 130. Such connections are compatible with the coordinated control scheme discussed above, which can keep bits stored in capacitors 120 from being simultaneously sent to the same, e.g., bitline. In some embodiments, multiple capacitors 120 on a common plateline 130 are controlled separately by using, e.g., separate wordlines on the gate electrodes 114 of the corresponding access transistors 110. In some such embodiments, drain contacts 118 are coupled to a same bitline. In some embodiments, multiple capacitors 120 on a common plateline 130 are controlled together by using, e.g., a common wordline on the gate electrodes 114 of the corresponding access transistors 110. In some such embodiments, drain contacts 118 are coupled to separate bitlines and bits are read or written simultaneously to or from different bitlines.

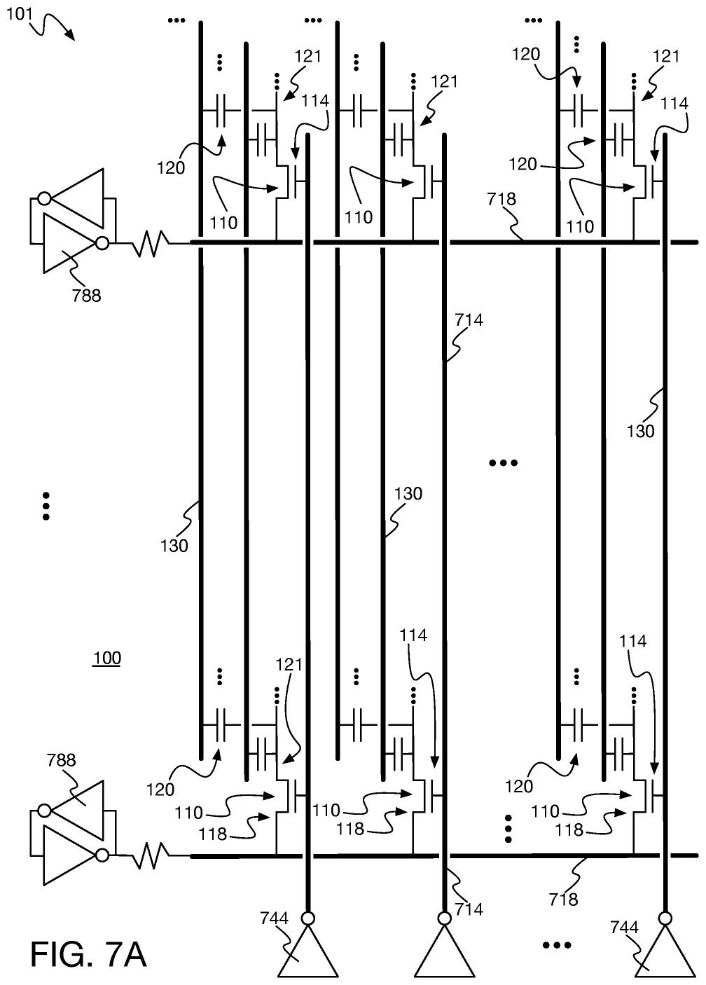

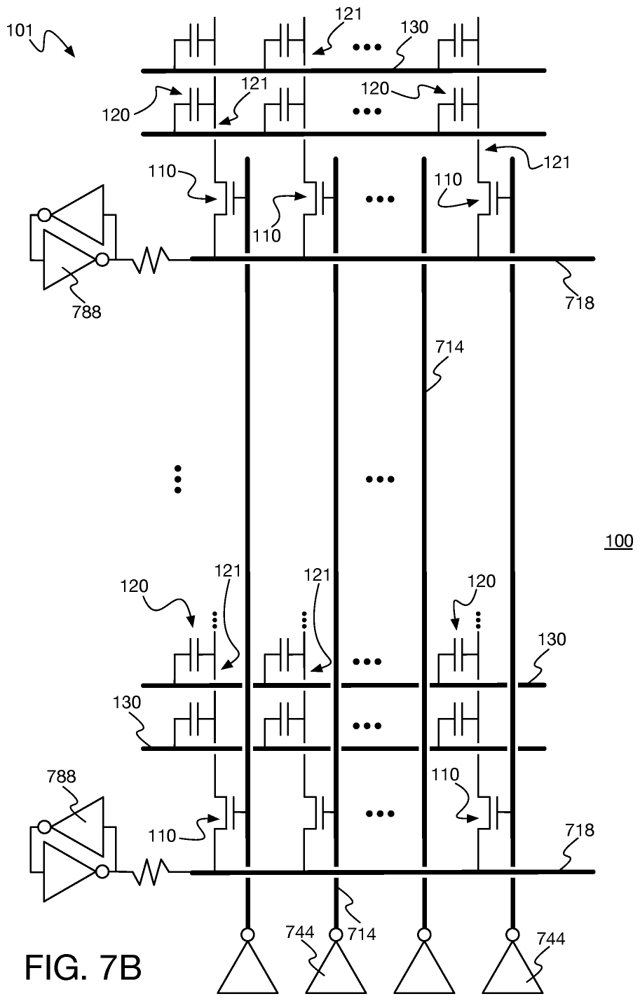

FIGS. 7A and 7B illustrate schematic views of memory device 101, including arrays of access transistors 110 and capacitors 120 in IC die 100, in accordance with some embodiments. FIGS. 7A and 7B show example wiring schemes for orthogonal bitlines 718 and wordlines 714. FIG. 7A illustrates capacitors 120 in memory device 101 with a schematic view that, although it cannot precisely represent the physical layout, can help show the organization of the device components electrically. Wordlines 714 are coupled to gate electrodes 114 of access transistors 110, and bitlines 718 are coupled to drain contacts 118 of access transistors 110. In the example of FIG. 7A, platelines 130 are parallel to wordlines 714, and bitlines 718 extend in a direction orthogonal to wordlines 714 and platelines 130. Other schemes may be used, one of which is shown in FIG. 7B. Platelines 130 couple groups of capacitors 120 by their separate plates (where capacitors 120 have different access transistors 110 and common plates 121). Common plates 121 couple groups of capacitors 120 by their the first plates (where capacitors 120 are coupled to different platelines 130). Ellipses throughout indicate that yet more wordlines 714, capacitors 120, access transistors 110, etc. are not shown or can be included in an arbitrarily large system. Driver circuits, such as bitline drivers 788 and wordline drivers 744, help source currents and maintain voltage levels as desired. The control signals on wordlines 714 (and gate electrodes 114) control the conduction of access transistors 110 to electrically connect (or not) bitlines 718 to storage capacitors 120.

Some examples of the schematic limitations should be pointed out. The physical layout of common plates 121 (and their corresponding groups of capacitors 120) and their relationships to other components cannot be accurately shown by this schematic view. The schematic symbols for capacitors 120 are flat, parallel plates, which are electrically connected on one side to schematically vertical electrical lines above access transistors 110. In some embodiments, these distinct capacitor plates are physically realized together as shared inner common plates 121, each surrounded by coaxial separate plates. In some embodiments, half of capacitors 120 and platelines 130 coupled to common plates 121 are physically above access transistors 110, and half of capacitors 120 and platelines 130 coupled to common plates 121 are physically below access transistors 110.

FIG. 7B shows another possible wiring scheme for the same, e.g., access transistors 110, capacitors 120 (with the same common plates 121, etc.), bitlines 718, wordlines 714, etc. Platelines 130 are parallel to bitlines 718, and wordlines 714 extend in a direction orthogonal to bitlines 718 and platelines 130. Ellipses throughout indicate that other components are present but not shown or can be included in an arbitrarily large system. Other wiring schemes are possible, e.g., where platelines 130 extend in a direction orthogonal to both bitlines 718 and wordlines 714, which also extend in directions orthogonal to the other.

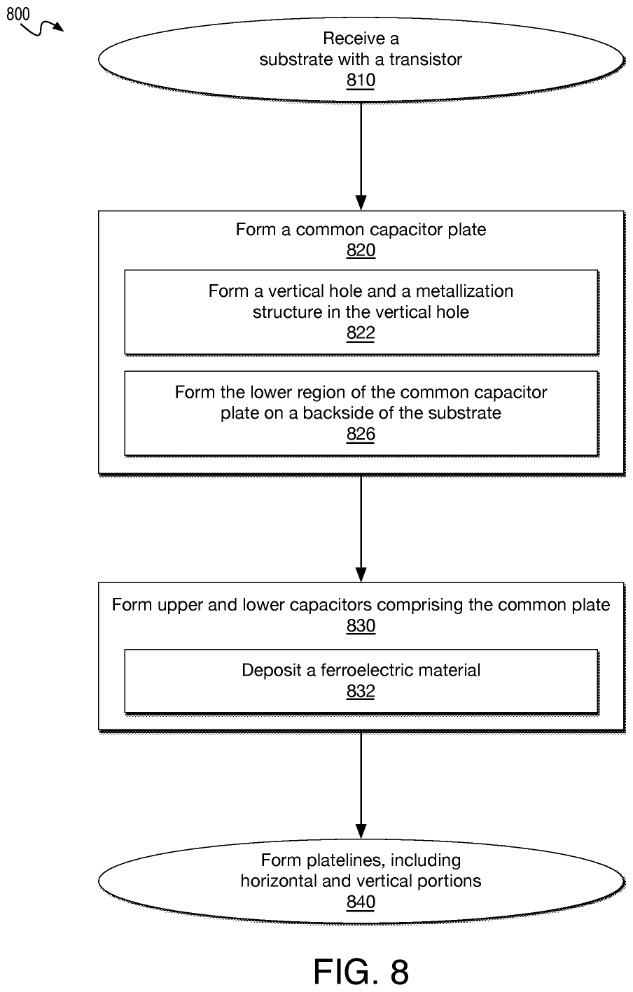

FIG. 8 illustrates various processes or methods for forming a layered, programmable capacitor array with shared common plate and single access transistor, in accordance with some embodiments. FIG. 8 shows methods 800 that includes operations 810-840. Some operations shown in FIG. 8 are optional. FIG. 8 shows an example sequence, but the operations can be done in other sequences as well, and some operations may be omitted. Some operations can also be performed multiple times before other operations are performed. Some operations may be included within other operations. Methods 800 generally entail forming groups of storage capacitors with a shared access transistor and a shared plate, common to the group and coupled to that transistor's channel.

In operation 810, a substrate with a transistor is received for forming an array of capacitors. The substrate is a planar platform and may be part of an IC die already including dielectric and metallization structures and, e.g., a non-planar transistor. The substrate may be one of many layers in an IC die, and may itself have many layers. The substrate may be above other layers in the IC die (all or of a portion of which may be subsequently removed in back-side metallization contexts), and other layers may subsequently be formed in or over the substrate.

The substrate may include any suitable material or materials. Any suitable semiconductor or other material can be used. A transistor may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, the substrate includes crystalline silicon and subsequent components are also silicon.

In operation 820, a common capacitor plate is formed and coupled to the source or drain of the transistor. This plate is a shared, common plate to be capacitively coupled to a group of unshared, separate plates. The common plate may be formed in separate stages, e.g., in portions corresponding to different layers in or over the substrate. The common plate should conduct sufficiently to allow charge to collect on the common plate side of a capacitor insulator or dielectric or, e.g., polarize ferroelectric material used as a capacitor dielectric. For example, the common plate may be formed of a metal convenient to and compatible with a standard manufacturing process, e.g., copper. In some embodiments, a metal is used for the common plate that is compatible with, e.g., a ferroelectric material used as a capacitor dielectric.

Operation 820 may include operation 822 and/or operation 826. In operation 822, a vertical hole is formed in the substrate above the source or the drain of the received transistor, and a metallization structure is formed in the vertical hole such that the metallization structure contacts said source or drain. In some embodiments, the vertical hole is vertically aligned with, e.g., a source contact and the metallization structure is formed with the same material as the source contact to form a single, integrated metallization structure including the source contact and common plate. In some embodiments, the vertical hole is dry etched, e.g., with a deep reactive ion etch (DRIE). In some such embodiments, the vertical hole is formed through the other plates, the unshared plates, after they have been formed. In some such embodiments, the vertical hole is formed through the insulators, e.g., ferroelectric material, after they have been formed. In some embodiments, the vertical hole is formed in the substrate and the metallization structure is formed as an inner plate after first depositing the unshared other plates and the insulators, e.g., on an outer surface of the vertical hole. The common plate need not be vertically oriented.

In operation 826, the substrate is inverted and a lower region of the common plate is formed on a backside of the substrate. For example, after the access transistor is formed and the substrate is received, an upper region of the common plate may be formed on a front side of the substrate. A carrier structure may then be coupled to the front side and the substrate inverted such that the back side is available for processing. The back side of the substrate can be ground down to very near the access transistor. The lower region of the common plate can be formed on the backside of the substrate, e.g., by similar methods as described in operation 822. The back side of the now-inverted substrate is above the access transistor, and a vertical hole can be formed in the substrate above, e.g., the source of the transistor. A metallization structure can be formed in the vertical hole and contacting the source and the upper region. In some embodiments, the lower region is formed concurrently with the upper region. In some such embodiments, a vertical hole is formed from the back side through the insulators and outer other plates already formed in both the front side and the back side. The lower region of the common plate can be vertically oriented and vertically aligned with the upper region of the common plate, but it need not be. In some embodiments, the lower region is offset from the upper region. In some embodiments, the lower region is not vertically oriented.

In operation 830, groups of capacitors are formed above and below the access transistor and including the common plate. A group of upper capacitors is formed that includes the upper common plate (or the upper region of the common plate) and a group of upper other plates. The other plates may be separate, outer plates that encircle the upper region or upper common plate. The upper region (or upper common plate) is formed such that it is coupled to and above the source or the drain of the access transistor. Each upper capacitor includes an upper other plate, an individual, exclusive portion of the upper region (or upper common plate), and an insulator between them. In some embodiments, the insulator includes a ferroelectric material.

A group of lower capacitors may be formed in a similar fashion but below the source or the drain of the access transistor. The group of lower capacitors includes the lower common plate (or the lower region of the common plate) and a group of lower other plates, e.g., separate, outer plates that encircle the lower common plate. The lower region (or lower common plate) is coupled to and below the source or the drain of the access transistor. Each lower capacitor includes an lower other plate, an individual, exclusive portion of the lower region (or lower common plate), and an insulator between them.

Operation 830 may include operation 832. In operation 832, a group of capacitors are ferroelectric capacitors, and a ferroelectric material is deposited over either the common plate or the separate, outer plates. In some embodiments, the ferroelectric material is deposited after one plate or group of plates is formed and before the other plate or group of plates is formed. In some embodiments, the common plate is an inner plate, and the separate plates are outer plates. In some such embodiments, a vertical hole is formed and the separate, outer plates are deposited on an outer surface of the hole, and the ferroelectric material is deposited, e.g., HZO by ALD, over the separate, outer plates before the inner common plate is formed in the hole. In some embodiments, a vertical hole is formed through the separate, outer plates after they are built up, one over the other, above the drain of the access transistor, and the ferroelectric material is deposited on an outer surface of the hole, internal to the separate, outer plates. In some embodiments, the ferroelectric material is deposited over the common plate, e.g., PZT over a planar surface of a horizontal common plate. The deposition of ferroelectric material can be performed similarly for the upper and lower capacitors, e.g., on a front or back side of the received substrate.

In operation 840, a group of platelines are formed with each plateline including a horizontal portion and a vertical portion. The platelines are formed such that the horizontal portions contact separate other plates and extend laterally outward from the capacitors. The vertical portions extend upward or downward from proximate ends contacting horizontal portions, nearer the transistor, to distal ends distal from the transistor. The platelines can be formed using any suitable method, e.g., damascene or double damascene. The horizontal portions can be formed before or after the vertical portions. The horizontal portions should be formed to allow for acceptable routing of the vertical portions. For example, horizontal portions nearer the access transistor, e.g., lower horizontal portions coupled to separate plates in an upper set of capacitors or upper horizontal portions coupled to separate plates in a lower set of capacitors, should extend laterally further away from the capacitors to allow for horizontal portions further from the access transistor, e.g., higher in an upper set of capacitors or lower in a lower set of capacitors, to extend laterally outward from the capacitors. Vertical portions can then extend vertically e.g., upward in an upper set of capacitors or downward in a lower set of capacitors, unimpeded by other horizontal and vertical portions. Vertical portions further from the access transistor, e.g., higher in an upper set of capacitors or lower in a lower set of capacitors, will be laterally nearer the capacitors.

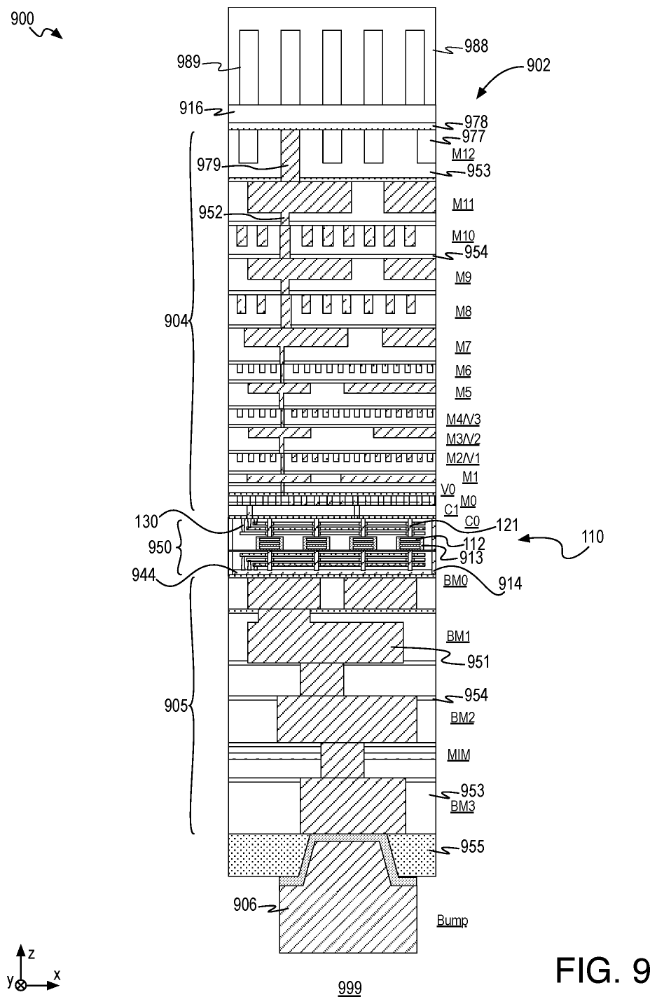

Layered multi-capacitor memory arrays with single access transistors may advantageously be integrated into a low-temperature system, such as that shown in FIG. 9, for improved operation. For example, some suitable materials, such as semiconductor materials, have increased carrier mobility, reduced leakage currents, and reduced contact resistance (e.g., at the interfaces between semiconductor and metal) at low temperatures. Such enhanced conduction can enable the use of, e.g., different materials and structures, such as smaller transistor channels. In some embodiments, access transistor channels as described (e.g., in fins, nanosheets, nanoribbons, or nanowires) have a thickness of 2 nm. In some embodiments, access transistor channels as described have a thickness of 1 nm. Lower temperatures may also enable the use of smaller capacitors or voltages. Lower temperatures reduce leakage currents in many insulator materials and can enable the use of, e.g., smaller capacitors. In some embodiments, capacitors in an array as described have a ferroelectric material thickness of 20 nm. Some materials allow for smaller structures or voltages. For example, HZO and similar materials may allow for deposition and operation of smaller ferroelectric material thicknesses than PZT and similar materials. In some embodiments, capacitors in an array as described have a ferroelectric material thickness of 10 nm. Smaller capacitors enable increased memory density. 2D materials can allow for ultrathin ferroelectric material thicknesses. In some embodiments, capacitors in an array as described have a ferroelectric material thickness of 2 nm.

A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC dies 100. In some embodiments, active cooling structures include channels on one or more sides of IC dies 100. In some embodiments, active cooling structures include channels within IC dies 100. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to 77K or below.

FIG. 9 illustrates a cross-sectional view of a low-temperature IC system 900 having layered capacitor memory arrays with single access transistors 110 and using die- and package-level active cooling, in accordance with some embodiments. In the example of IC system 900, IC die 902 includes active-cooling structures or components as provided by both die-level microchannels 977 and package-level active-cooling structure 988. IC system 900 includes a lateral surface along the x-y plane that may be defined or taken at any vertical position of IC system 900. The lateral surface of the x-y plane is orthogonal to a vertical or build-up dimension as defined by the z-axis. In some embodiments, IC system 900 may be formed from any substrate material suitable for the fabrication of transistor circuitry. In some embodiments, a semiconductor substrate is used to manufacture non-planar access transistors 110 and other transistors and components of IC system 900. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 9, IC system 900 includes an IC die 902, which is a monolithic IC with multi-capacitor memory arrays as described above, including non-planar access transistors 110, front-side metallization layers 904 (or front-side interconnect layers), and optional back-side metallization layers 905 (or back-side interconnect layers). As shown, access transistors 110 are transistors embedded within a dielectric layer 950. As shown, each of access transistors 110 include transistor channels 112 (e.g., within nanoribbons or nanosheets) and gate structures 913. Each of access transistors 110 also include source and drain structures, and source and drain contacts, which are not shown in the cross-section of FIG. 9. Platelines 130 connect capacitor arrays sharing common plates 121 with arrays sharing other common plates. In some embodiments, front-side metallization layers 904 provide signal routing to access transistors 110 and back-side metallization layers 905 provide power delivery, as enabled by through-contacts 914, to access transistors 110. In some embodiments, IC system 900 further includes a package-level cooling structure 988, which may be deployed on or over front-side metallization layers 904 (as shown) or on or over a back-side of IC die 902. In some embodiments, package-level cooling structure 988 is coupled to IC die 902 by an adhesion layer 916. IC system 900 may also be deployed without back-side metallization layers 905 shown in FIG. 9. In such embodiments, signal routing and power are provided to access transistors 110 via front-side metallization layers 904. However, use of back-side metallization layers 905 may offer advantages.

Access transistors 110 are connected and thermally coupled by metallization, e.g., metal heat spreader 944, to the entire metallization structure by through-contacts 914. In this way, access transistors 110 are thermally coupled to both the die-level active-cooling structures (of die-level microchannels 977) and package-level active-cooling structure 988.

Interconnectivity of access transistors 110 (and other transistors, etc.), signal routing to and from capacitor memory arrays, etc., power delivery, etc., and routing to an outside device (not shown), is provided by front-side metallization layers 904, optional back-side metallization layers 905, and package-level interconnects 906. In the example of FIG. 9, package-level interconnects 906 are provided on or over a back-side of IC die 902 as bumps over a passivation layer 955, and IC system 900 is attached to a substrate 999 (and coupled to signal routing to, power delivery, etc.) by package-level interconnects 906. However, package-level interconnects 906 may be provided using any suitable interconnect structures such as bond pads, solder bumps, etc. Furthermore, in some embodiments, package-level interconnects 906 are provided on or over a front-side of IC die 902 (i.e., over front-side metallization layers 904) and package-level cooling structure 988 is provided on or over a back-side of IC die 902.

In IC system 900, IC die 902 includes die-level, active-cooling as provided by die-level microchannels 977. Die-level microchannels 977 are to convey a heat transfer fluid therein to remove heat from IC die 902. The heat transfer fluid may be any suitable liquid or gas. In some embodiments, the heat transfer fluid is liquid nitrogen operable to lower the temperature of IC die 902 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 977 may be provided in any pattern in the x-y plane such as serpentine patterns, patterns of multiple parallel die-level microchannels 977, or the like. Die-level microchannels 977 couple to a heat exchanger (not shown) that removes heat from and cools the heat transfer fluid before re-introduction to die-level microchannels 977. The flow of fluid within die-level microchannels 977 may be provided by a pump or other fluid flow device. The operation of the heat exchanger, pump, etc. may be controlled by a controller.

In the illustrated embodiment, die-level microchannels 977 are implemented at metallization level M12. In other embodiments, die-level microchannels 977 are implemented over metallization level M12. Die-level microchannels 977 may be formed using any suitable technique or techniques such as patterning and etch techniques to form the void structures of die-level microchannels 977 and passivation or deposition techniques to form a cover structure 978 to enclose the void structures. As shown, in some embodiments, the die-level, active-cooling structure of IC system 900 includes a number of die-level microchannels 977 in IC die 902 and over a number of front-side metallization layers 904. As discussed, die-level microchannels 977 are to convey a heat transfer fluid therein. In some embodiments, a metallization feature 979 of metallization layer M12 is laterally adjacent to die-level microchannels 977. For example, metallization feature 979 may couple to a package-level interconnect structure (not shown) for signal routing for IC die 902. In some embodiments, a passive heat removal device such as a heat sink or the like may be used instead of or in addition to package-level cooling structure 988. In some embodiments, package-level cooling structure 988 is not deployed in IC system 900.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 951, are interconnected by vias, such as vias 952, that may be characterized as part of the metallization layers or between the metallization layers. As shown, in some embodiments, front-side metallization layers 904 are formed over and immediately adjacent access transistors 110. The back-side is then the opposite side, which may be exposed during processing by attaching the front-side to a carrier wafer and exposing the back-side (e.g., by back-side grind or etch operations) as known in the art.

In the illustrated example, front-side metallization layers 904 include M0, V0, M1, M2/V1, M3/V2, M4/V3, and M4-M12. However, front-side metallization layers 904 may include any number of metallization layers such as eight or more metallization layers. Similarly, back-side metallization layers 905 include BM0, BM1, BM2, and BM3. However, back-side metallization layers 905 may include any number of metallization layers such as two to five metallization layers. Front-side metallization layers 904 and back-side metallization layers 905 are embedded within dielectric materials 953, 954. Furthermore, optional metal-insulator-metal (MIM) devices such as diode devices may be provided within back-side metallization layers 905. Other devices such as capacitive memory devices may be provided within front-side metallization layers 904 and/or back-side metallization layers 905.

IC system 900 includes package-level active-cooling structure 988 having package-level microchannels 989. Package-level microchannels 989 are to convey a heat transfer fluid therein to remove heat from IC die 902. The heat transfer fluid may be any suitable liquid or gas as discussed with respect to die-level microchannels 977. Package-level microchannels 989 may be provided in any pattern in the x-y plane such as serpentine patterns, patterns of multiple parallel package-level microchannels 989, etc. Package-level microchannels 989 couple to a heat exchanger (not shown) that removes heat from and cools the heat transfer fluid before re-introduction to package-level microchannels 989. The flow of fluid within package-level microchannels 989 may be provided by a pump or other fluid-flow device. The operation of the heat exchanger, pump, etc. may be controlled by a controller. In the illustrated embodiment, package-level active-cooling structure 988 is a chiller mounted to IC die 902 such that the chiller has a solid body having microchannels therein to convey a heat transfer fluid.

In some embodiments, the heat-removal fluid deployed in die-level microchannels 977 and package-level active-cooling structure 988 are coupled to the same pump and heat exchanger systems. In such embodiments, the heat removal fluid conveyed in both die-level microchannels 977 and package-level active-cooling structure 988 are the same material. Such embodiments may advantageously provide simplicity. In other embodiments, the heat removal fluids are controlled separately. In such embodiments, the heat removal fluids conveyed by die-level microchannels 977 and package-level active-cooling structure 988 may be the same or they may be different. Such embodiments may advantageously provide improved flexibility.

As discussed, IC system 900 includes IC die 902 and optional die-level and package-level active-cooling structures operable to remove heat from IC die 902 to achieve a very low operating temperature of IC die 902. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. (e.g., 77K) may be used. In some embodiments, the operating temperature is in a cryogenic temperature operating window (e.g., about −180° C. to about −70° C.). The active-cooling structure may be provided as a package-level structure (i.e., separable from IC die 902), as a die-level structure (i.e., integral to IC die 902), or both. In some embodiments, IC die 902 is deployed in a cold environment, formed using sufficiently conductive materials, etc. and an active-cooling structure is not used.

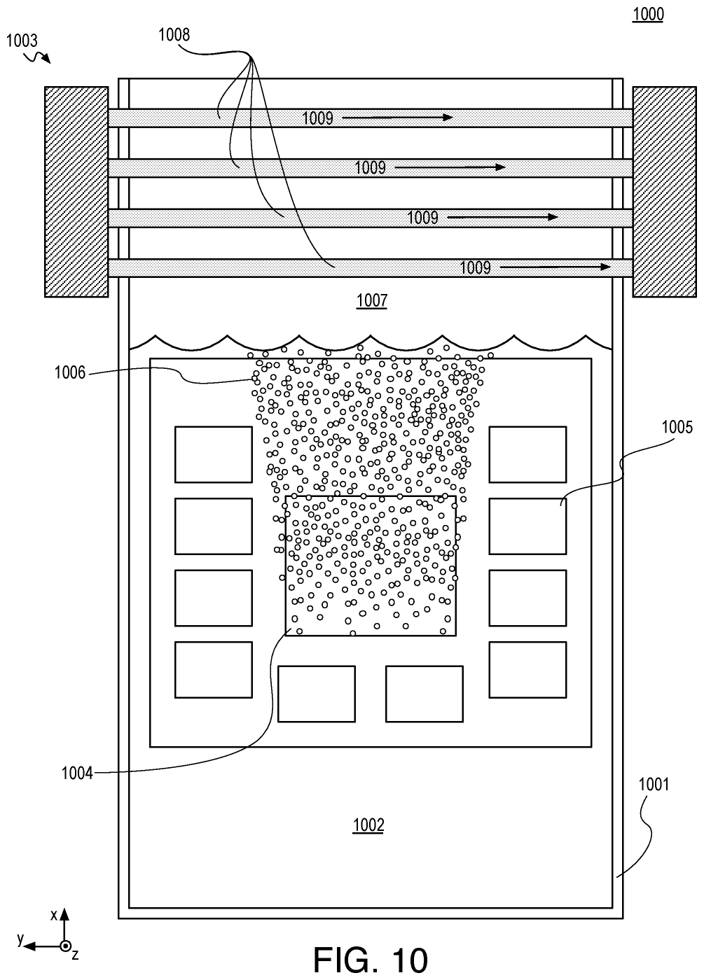

FIG. 10 illustrates a view of an example two-phase immersion cooling system for low-temperature operation of an IC system, in accordance with some embodiments. As shown, two-phase immersion cooling system 1000 includes a fluid containment structure 1001, a low-boiling point liquid 1002 within fluid containment structure 1001, and a condensation structure 1003 at least partially within fluid containment structure 1001. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 1004, such as an IC package including any of IC dies or systems 100, 900 as discussed herein is immersed in low-boiling point liquid 1002. In some embodiments, IC dies or systems 100, 900 as deployed in two-phase immersion cooling system 1000 do not include additional active cooling structures, although such die-level or package-level active cooling structures may be used in concert with two-phase immersion cooling system 1000. In some embodiments, when deployed in two-phase immersion cooling system 1000, package-level active-cooling structure 988 is a heat sink, a heat dissipation plate, a porous heat dissipation plate or the like.

Notably, IC die 902 (or IC die 100), is the source of heat in the context of two-phase immersion cooling system 1000. For example, IC die 902 may be packaged and mounted on electronics substrate 1005. Electronic substrate 1005 may be coupled to a power supply (not shown) and may be partially or completely submerged in low-boiling point liquid 1002.

In operation, the heat produced by heat generation source 1004 vaporizes low-boiling point liquid 1002 as shown in vapor or gas state as bubbles 1006, which may collect, due to gravitational forces, above low-boiling point liquid 1002 as a vapor portion 1007 within fluid containment structure 1001. Condensation structure 1003 may extend through vapor portion 1007. In some embodiments, condensation structure 1003 is a heat exchanger having a number of tubes 1008 with a cooling fluid (i.e., a fluid colder than the condensation point of vapor portion 1007) shown by arrows 1009 that may flow through tubes 1008 to condense vapor portion 1007 back to low-boiling point liquid 1002. In the IC system of FIG. 9, package-level active-cooling structure 988 includes a passive cooling structure such as a heat sink for immersion in low-boiling point liquid 1002.

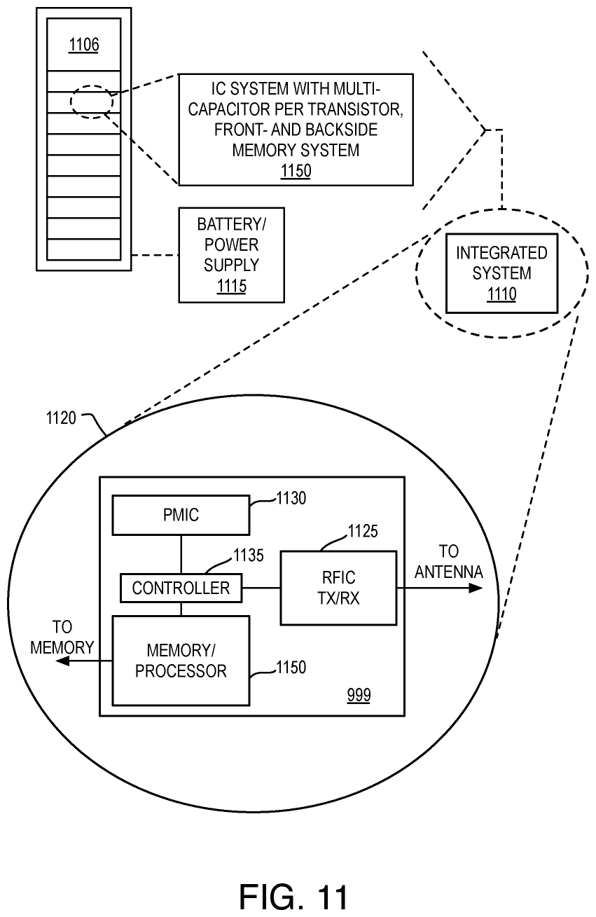

FIG. 11 illustrates a diagram of an example data server machine employing an IC system having layered capacitor memory arrays with single access transistors, in accordance with some embodiments. Server machine 1106 may be any commercial server, for example, including any number of high-performance computing platforms disposed within a rack and networked together for electronic data processing, which in the exemplary embodiment includes one or more devices 1150 having layered, programmable capacitor arrays per access transistor.

Also as shown, server machine 1106 includes a battery and/or power supply 1115 to provide power to devices 1150, and to provide, in some embodiments, power delivery functions such as power regulation. Devices 1150 may be deployed as part of a package-level integrated system 1110. Integrated system 1110 is further illustrated in the expanded view 1120. In the exemplary embodiment, devices 1150 (labeled “Memory/Processor”) includes at least one memory chip (e.g., with a programmable capacitor array), and/or at least one processor chip (e.g., a microprocessor, a multi-core microprocessor, or graphics processor, or the like) having the characteristics discussed herein. In an embodiment, device 1150 is a microprocessor including a programmable capacitor memory array memory. As shown, device 1150 may be a multi-chip module employing one or more IC dies with layered, programmable capacitor arrays per access transistor, as discussed herein. Device 1150 may be further coupled to (e.g., communicatively coupled to) a board, an interposer, or other substrate 999 along with, one or more of a power management IC (PMIC) 1130, RF (wireless) IC (RFIC) 1125, including a wideband RF (wireless) transmitter and/or receiver (TX/RX) (e.g., including a digital baseband and an analog front end module further comprises a power amplifier on a transmit path and a low noise amplifier on a receive path), and a controller 1135 thereof. In some embodiments, RFIC 1125, PMIC 1130, controller 1135, and device 1150 include IC dies having layered, programmable capacitor arrays per access transistor on substrate 999 in a multi-chip module.

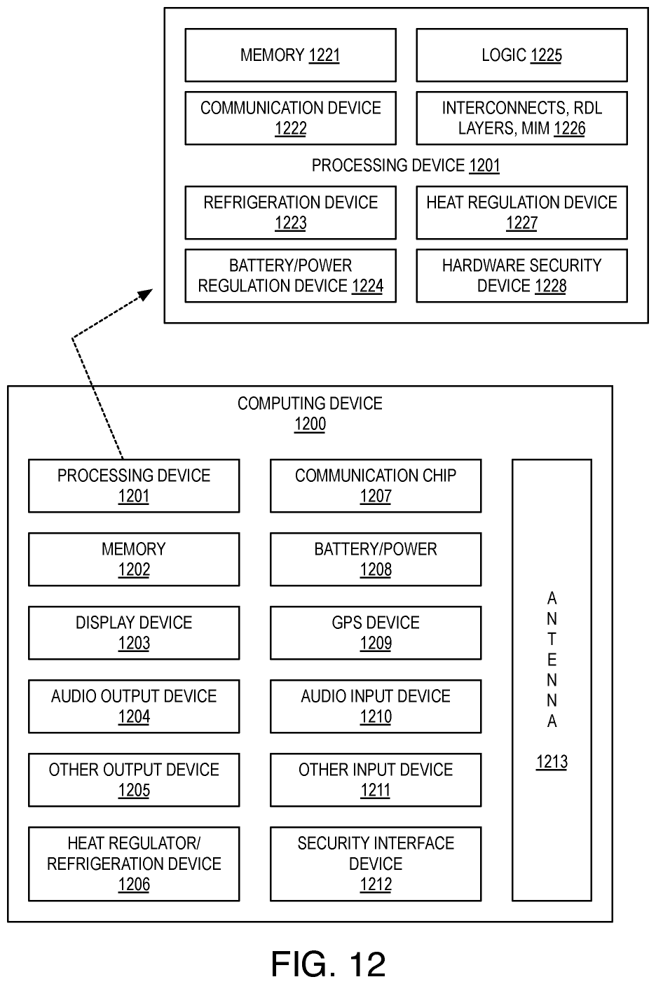

FIG. 12 is a block diagram of an example computing device 1200, in accordance with some embodiments. For example, one or more components of computing device 1200 may include any of the devices or structures discussed herein. A number of components are illustrated in FIG. 12 as being included in computing device 1200, but any one or more of these components may be omitted or duplicated, as suitable for the application. In some embodiments, some or all of the components included in computing device 1200 may be attached to one or more printed circuit boards (e.g., a motherboard). In some embodiments, various ones of these components may be fabricated onto a single system-on-a-chip (SoC) die. Additionally, in various embodiments, computing device 1200 may not include one or more of the components illustrated in FIG. 12, but computing device 1200 may include interface circuitry for coupling to the one or more components. For example, computing device 1200 may not include a display device 1203, but may include display device interface circuitry (e.g., a connector and driver circuitry) to which display device 1203 may be coupled. In another set of examples, computing device 1200 may not include an audio output device 1204, other output device 1205, global positioning system (GPS) device 1209, audio input device 1210, or other input device 1211, but may include audio output device interface circuitry, other output device interface circuitry, GPS device interface circuitry, audio input device interface circuitry, audio input device interface circuitry, to which audio output device 1204, other output device 1205, GPS device 1209, audio input device 1210, or other input device 1211 may be coupled.

Computing device 1200 may include a processing device 1201 (e.g., one or more processing devices). As used herein, the term “processing device” or “processor” indicates a device that processes electronic data from registers and/or memory (such as a memory device including a programmable capacitor array) to transform that electronic data into other electronic data that may be stored in registers and/or memory. Processing device 1201 may include a memory 1221 (including a programmable capacitor array), a communication device 1222, a refrigeration device 1223, a battery/power regulation device 1224, logic 1225, interconnects 1226 (i.e., optionally including redistribution layers (RDL) or metal-insulator-metal (MIM) devices), a heat regulation device 1227, and a hardware security device 1228.

Processing device 1201 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1200 may include a memory 1202, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1202 includes memory that shares a die with processing device 1201. This memory may be used as cache memory and may include embedded dynamic random-access memory (eDRAM) or spin transfer torque magnetic random-access memory (STT-M RAM).

Computing device 1200 may include a heat regulation/refrigeration device 1206. Heat regulation/refrigeration device 1206 may maintain processing device 1201 (and/or other components of computing device 1200) at a predetermined low temperature during operation. This predetermined low temperature may be any temperature discussed herein.

In some embodiments, computing device 1200 may include a communication chip 1207 (e.g., one or more communication chips). For example, the communication chip 1207 may be configured for managing wireless communications for the transfer of data to and from computing device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1207 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1207 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1207 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1207 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1207 may operate in accordance with other wireless protocols in other embodiments. Computing device 1200 may include an antenna 1213 to facilitate wireless communications and/or to receive other wireless communications (such as AM or FM radio transmissions).

In some embodiments, communication chip 1207 may manage wired communications, such as electrical, optical, or any other suitable communication protocols (e.g., the Ethernet). As noted above, communication chip 1207 may include multiple communication chips. For instance, a first communication chip 1207 may be dedicated to shorter-range wireless communications such as Wi-Fi or Bluetooth, and a second communication chip 1207 may be dedicated to longer-range wireless communications such as GPS, EDGE, GPRS, CDMA, WiMAX, LTE, EV-DO, or others. In some embodiments, a first communication chip 1207 may be dedicated to wireless communications, and a second communication chip 1207 may be dedicated to wired communications.

Computing device 1200 may include battery/power circuitry 1208. Battery/power circuitry 1208 may include one or more energy storage devices (e.g., batteries or capacitors) and/or circuitry for coupling components of computing device 1200 to an energy source separate from computing device 1200 (e.g., AC line power).

Computing device 1200 may include a display device 1203 (or corresponding interface circuitry, as discussed above). Display device 1203 may include any visual indicators, such as a heads-up display, a computer monitor, a projector, a touchscreen display, a liquid crystal display (LCD), a light-emitting diode display, or a flat panel display, for example.

Computing device 1200 may include an audio output device 1204 (or corresponding interface circuitry, as discussed above). Audio output device 1204 may include any device that generates an audible indicator, such as speakers, headsets, or earbuds, for example.

Computing device 1200 may include an audio input device 1210 (or corresponding interface circuitry, as discussed above). Audio input device 1210 may include any device that generates a signal representative of a sound, such as microphones, microphone arrays, or digital instruments (e.g., instruments having a musical instrument digital interface (MIDI) output).

Computing device 1200 may include a GPS device 1209 (or corresponding interface circuitry, as discussed above). GPS device 1209 may be in communication with a satellite-based system and may receive a location of computing device 1200, as known in the art.

Computing device 1200 may include other output device 1205 (or corresponding interface circuitry, as discussed above). Examples of the other output device 1205 may include an audio codec, a video codec, a printer, a wired or wireless transmitter for providing information to other devices, or an additional storage device.

Computing device 1200 may include other input device 1211 (or corresponding interface circuitry, as discussed above). Examples of the other input device 1211 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1200 may include a security interface device 1212. Security interface device 1212 may include any device that provides security measures for computing device 1200 such as intrusion detection, biometric validation, security encode or decode, access list management, malware detection, or spyware detection.

Computing device 1200, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-12. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, a memory device comprises an access transistor comprising a channel between a source and a drain, a plurality of first capacitors comprising a first shared plate and a plurality of first separate plates, the first shared plate coupled to and above the source or the drain, wherein individual ones of the first capacitors comprise one of the first separate plates, a portion of the first shared plate, and a first insulator therebetween, a plurality of second capacitors comprising a second shared plate and a plurality of second separate plates, the second shared plate coupled to and below the source or the drain, wherein individual ones of the second capacitors comprise one of the second separate plates, a portion of the second shared plate, and a second insulator therebetween, and a plurality of platelines, individual ones of the platelines electrically connected to corresponding ones of the first and second separate plates.

In one or more second embodiments, further to the first embodiments, individual ones of the first and second insulators comprise a ferroelectric material.

In one or more third embodiments, further to the first or second embodiments, the ferroelectric material comprises oxygen and one or more of hafnium, zirconium, strontium, niobium, lanthanum, lead, and titanium.

In one or more fourth embodiments, further to the first through third embodiments, the ferroelectric material has a capacitance of at least 1 fF and not more than 30 fF.

In one or more fifth embodiments, further to the first through fourth embodiments, the ferroelectric material has a thickness of at least 2 nm and not more than 20 nm.

In one or more sixth embodiments, further to the first through fifth embodiments, the first and second capacitors are vertically aligned.

In one or more seventh embodiments, further to the first through sixth embodiments, the first capacitors are on a front side of an IC die, and the second capacitors are on a back side of the IC die.

In one or more eighth embodiments, further to the first through seventh embodiments, the first and second shared plates comprise first and second vertical regions, respectively, and individual ones of the first and second separate plates encircle the first and second shared plates in horizontal planes spaced at heights along the first and second vertical regions.

In one or more ninth embodiments, further to the first through eighth embodiments, individual ones of the platelines comprise a horizontal portion and a vertical portion, the first and second separate plates coupled to vertical portions by horizontal portions, a first vertical portion and a first horizontal portion coupled to a proximate separate plate, and a second vertical portion and a second horizontal portion coupled to a distal separate plate, the proximate separate plate and the distal separate plate both above or below the access transistor, the proximate separate plate nearer the access transistor than a distal separate plate, the second vertical portion laterally between the first or second shared plate and the first vertical portion, and the first horizontal portion extending laterally beyond the second horizontal portion.

In one or more tenth embodiments, further to the first through ninth embodiments, the portion of the shared plate of an individual one of the capacitors has a first thickness below a second thickness and above a third thickness, the first thickness being wider than the second and third thicknesses.

In one or more eleventh embodiments, further to the first through tenth embodiments, the access transistor is a non-planar transistor, and the channel is within a substantially vertical fin.

In one or more twelfth embodiments, further to the first through eleventh embodiments, the access transistor is a non-planar transistor, and the channel is within a nanosheet or nanowire.

In one or more thirteenth embodiments, an IC system comprises an IC die comprising a plurality of ferroelectric capacitors and a select transistor, the ferroelectric capacitors sharing an inner common plate, the select transistor comprising a channel between a source and a drain, the inner common plate electrically connected to the source or the drain, and the plurality of ferroelectric capacitors comprising a lower set of outer plates and an upper set of outer plates, the lower set below the select transistor and the upper set above the select transistor, a substrate, the IC die coupled to the substrate, and a power supply, the power supply coupled to the IC die.

In one or more fourteenth embodiments, further to the thirteenth embodiments, the lower set is on a front side of the IC die, and the upper set is on a back side of the IC die.

In one or more fifteenth embodiments, further to the thirteenth or fourteenth embodiments, the IC system comprises or is thermally coupled to a cooling structure, the cooling structure operable to remove heat from the IC die to achieve an operating temperature at or below 0° C.

In one or more sixteenth embodiments, further to the thirteenth through fifteenth embodiments, the select transistor is a non-planar transistor, and a thickness of the channel is not more than 2 nm.

In one or more seventeenth embodiments, further to the thirteenth through sixteenth embodiments, one of the ferroelectric capacitors has a capacitance of at least 0.1 fF and not more than 5 fF.

In one or more eighteenth embodiments, a method comprises receiving a substrate, the substrate comprising a transistor, forming a common plate, the common plate coupled to a source or a drain of the transistor, forming a plurality of upper capacitors comprising an upper region of the common plate and a plurality of upper other plates, the upper region coupled to and above the source or the drain, wherein individual ones of the upper capacitors comprise one of the upper other plates, an exclusive portion of the upper region, and a first insulator therebetween, and forming a plurality of lower capacitors comprising a lower region of the common plate and a plurality of lower other plates, the lower region coupled to and below the source or the drain, wherein individual ones of the lower capacitors comprise one of the lower other plates, an exclusive portion of the lower region, and a second insulator therebetween.

In one or more nineteenth embodiments, further to the eighteenth embodiments, forming said common plate comprises inverting the substrate and, on a backside of the substrate, forming the lower region of the common plate.

In one or more twentieth embodiments, further to the eighteenth or nineteenth embodiments, forming said common plate comprises forming a vertical hole above the source or the drain and forming a metallization structure in the vertical hole, the metallization structure contacting the source or the drain.

In one or more twenty-first embodiments, further to the eighteenth through twentieth embodiments, forming a plurality of upper or lower capacitors comprises depositing a ferroelectric material over the common plate or individual ones of the upper or lower other plates.

In one or more twenty-second embodiments, further to the eighteenth through twenty-first embodiments, the method further comprises forming a plurality of platelines, individual ones of the platelines comprising horizontal portions and vertical portions, horizontal portions contacting individual ones of the upper and lower other plates, and vertical portions extending from proximate ends contacting horizontal portions to distal ends distal from the transistor.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. A memory device, comprising:
an access transistor comprising a channel between a source and a drain;
a plurality of first capacitors comprising a first shared plate and a plurality of first separate plates, the first shared plate coupled to and above the source or the drain, wherein individual ones of the first capacitors comprise one of the first separate plates, a portion of the first shared plate, and a first insulator therebetween;
a plurality of second capacitors comprising a second shared plate and a plurality of second separate plates, the second shared plate coupled to and below the source or the drain, wherein individual ones of the second capacitors comprise one of the second separate plates, a portion of the second shared plate, and a second insulator therebetween; and
a plurality of platelines, individual ones of the platelines electrically connected to corresponding ones of the first and second separate plates.

2. The memory device of claim 1, wherein individual ones of the first and second insulators comprise a ferroelectric material.

3. The memory device of claim 2, wherein the ferroelectric material comprises oxygen and one or more of hafnium, zirconium, strontium, niobium, lanthanum, lead, and titanium.

4. The memory device of claim 2, wherein the ferroelectric material has a capacitance of at least 1 fF and not more than 30 fF.

5. The memory device of claim 2, wherein the ferroelectric material has a thickness of at least 2 nm and not more than 20 nm.

6. The memory device of claim 1, wherein the first and second capacitors are vertically aligned.

7. The memory device of claim 1, wherein the first capacitors are on a front side of an integrated circuit (IC) die, and the second capacitors are on a back side of the IC die.

8. The memory device of claim 1, wherein the first and second shared plates comprise first and second vertical regions, respectively, and individual ones of the first and second separate plates encircle the first and second shared plates in horizontal planes spaced at heights along the first and second vertical regions.

9. The memory device of claim 8, wherein individual ones of the platelines comprise a horizontal portion and a vertical portion, the first and second separate plates coupled to vertical portions by horizontal portions, a first vertical portion and a first horizontal portion coupled to a proximate separate plate, and a second vertical portion and a second horizontal portion coupled to a distal separate plate, the proximate separate plate and the distal separate plate both above or below the access transistor, the proximate separate plate nearer the access transistor than a distal separate plate, the second vertical portion laterally between the first or second shared plate and the first vertical portion, and the first horizontal portion extending laterally beyond the second horizontal portion.

10. The memory device of claim 8, wherein the portion of the shared plate of an individual one of the capacitors has a first thickness below a second thickness and above a third thickness, the first thickness being wider than the second and third thicknesses.

11. The memory device of claim 10, wherein the access transistor is a non-planar transistor, and the channel is within a substantially vertical fin.

12. The memory device of claim 10, wherein the access transistor is a non-planar transistor, and the channel is within a nanosheet or nanowire.

13. An integrated circuit (IC) system, comprising:
an IC die comprising a plurality of ferroelectric capacitors and a select transistor, the ferroelectric capacitors sharing an inner common plate, the select transistor comprising a channel between a source and a drain, the inner common plate electrically connected to the source or the drain, and the plurality of ferroelectric capacitors comprising a lower set of outer plates and an upper set of outer plates, the lower set below the select transistor and the upper set above the select transistor;
a substrate, the IC die coupled to the substrate; and
a power supply, the power supply coupled to the IC die.

14. The IC system of claim 13, wherein the lower set is on a front side of the IC die, and the upper set is on a back side of the IC die.

15. The IC system of claim 13, wherein the IC system comprises or is thermally coupled to a cooling structure, the cooling structure operable to remove heat from the IC die to achieve an operating temperature at or below 0° C.

16. The IC system of claim 15, wherein the select transistor is a non-planar transistor, and a thickness of the channel is not more than 2 nm.

17. The IC system of claim 15, wherein one of the ferroelectric capacitors has a capacitance of at least 0.1 fF and not more than 5 fF.

18. A method, comprising:
receiving a substrate, the substrate comprising a transistor;
forming a common plate, the common plate coupled to a source or a drain of the transistor;
forming a plurality of upper capacitors comprising an upper region of the common plate and a plurality of upper other plates, the upper region coupled to and above the source or the drain, wherein individual ones of the upper capacitors comprise one of the upper other plates, an exclusive portion of the upper region, and a first insulator therebetween; and
forming a plurality of lower capacitors comprising a lower region of the common plate and a plurality of lower other plates, the lower region coupled to and below the source or the drain, wherein individual ones of the lower capacitors comprise one of the lower other plates, an exclusive portion of the lower region, and a second insulator therebetween.

19. The method of claim 18, wherein forming said common plate comprises inverting the substrate and, on a backside of the substrate, forming the lower region of the common plate.

20. The method of claim 18, wherein forming said common plate comprises forming a vertical hole above the source or the drain and forming a metallization structure in the vertical hole, the metallization structure contacting the source or the drain.

21. The method of claim 18, wherein forming a plurality of upper or lower capacitors comprises depositing a ferroelectric material over the common plate or individual ones of the upper or lower other plates.

22. The method of claim 18, further comprising forming a plurality of platelines, individual ones of the platelines comprising horizontal portions and vertical portions, horizontal portions contacting individual ones of the upper and lower other plates, and vertical portions extending from proximate ends contacting horizontal portions to distal ends distal from the transistor.
